(19) United States
(12) Patent Application Publication
(10) Pub. No.: US 2026/0223693 A1
(43) Pub. Date: Jul. 30, 2026

(54) SEMICONDUCTOR DEVICE AND METHOD FOR MANUFACTURING SEMICONDUCTOR DEVICE

(71) Applicant: ROHM CO., LTD., Kyoto-shi (JP)

(72) Inventor: Naoyuki SANO, Kyoto (JP)

(21) Appl. No.: 19/578,557

(22) Filed: Mar. 25, 2026

Related U.S. Application Data
(63) Continuation of application No. PCT/JP2024/035436, filed on Oct. 3, 2024.

(30) Foreign Application Priority Data
Oct. 4, 2023 (JP) 2023-173183

(51) Int. Cl. H10W 70/40; H10W 74/10

(52) U.S. Cl. CPC H10W 70/421; H10W 74/111

(57) ABSTRACT

A semiconductor device includes a plurality of terminals, a semiconductor chip mounted on the plurality of terminals, and a sealing resin for sealing the plurality of terminals and the semiconductor chip. Each of the plurality of terminals includes: a rear surface, at least a part of which is exposed from the sealing resin; a front surface on which the semiconductor chip is mounted; a tip surface which is provided within the sealing resin and which is an end surface in a first direction orthogonal to the Z direction; and a projecting portion which is positioned at an intermediate portion in the Z direction on the tip surface.

### CROSS-REFERENCE TO RELATED APPLICATIONS

This application is a continuation of, and claims the benefit of priority from International Application No. PCT/JP2024/035436, filed on October 3, 2024, which claims the benefit of priority from Japanese Patent Application No. 2023-173183, filed on October 4, 2023, the entire contents of each are incorporated herein by reference.

### BACKGROUND

### 1. Field

The following description relates to a semiconductor device and a method for manufacturing a semiconductor device.

### 2. Description of Related Art

JP2020-188083A discloses a semiconductor device that includes a lead frame, a semiconductor element including pillars soldered to the lead frame, and a resin encapsulating the lead frame and the semiconductor element.

### BRIEF DESCRIPTION OF DRAWINGS

FIG. 1 is a schematic perspective view showing an embodiment of a semiconductor device.

FIG. 2 is a schematic plan view showing the inside of the semiconductor device shown in FIG. 1.

FIG. 3 is a schematic bottom view of the semiconductor device shown in FIG. 1.

FIG. 4 is a schematic cross-sectional view of the semiconductor device taken along line F4-F4 in FIG. 2.

FIG. 5 is an enlarged schematic cross-sectional view of the semiconductor device shown in FIG. 4.

FIG. 6 is a schematic plan view showing an exemplary manufacturing step of an embodiment of a semiconductor device.

FIG. 7 is a schematic end view of a metal plate taken along line F7-F7 in FIG. 6.

FIG. 8 is a schematic end view showing a manufacturing step subsequent to the step shown in FIG. 7.

FIG. 9 is a schematic end view showing a manufacturing step subsequent to the step shown in FIG. 8.

FIG. 10 is a schematic end view showing a manufacturing step subsequent to the step shown in FIG. 9.

FIG. 11 is a schematic end view showing a manufacturing step subsequent to the step shown in FIG. 10.

FIG. 12 is a schematic end view showing a manufacturing step subsequent to the step shown in FIG. 11.

FIG. 13 is a schematic cross-sectional view showing a manufacturing step subsequent to the step of FIG. 12.

FIG. 14 is a schematic cross-sectional view showing a comparative example of a semiconductor device.

FIG. 15 is a schematic end view showing a manufacturing step of the semiconductor device of the comparative example.

FIG. 16 is a schematic end view showing a manufacturing step subsequent to the step shown in FIG. 15.

### DETAILED DESCRIPTION

Embodiments of a semiconductor device according to the present disclosure will now be described with reference to the accompanying drawings. In the drawings, components may not be drawn to scale for simplicity and clarity of illustration. To facilitate understanding, hatching lines may not be shown in the cross-sectional drawings. The accompanying drawings merely illustrate exemplary embodiments of the present disclosure and are not intended to limit the present disclosure.

This detailed description includes exemplary embodiments of devices, systems, and methods in accordance with the present disclosure. Further, this detailed description is illustrative and is not intended to limit embodiments of the present disclosure or application and use of the embodiments.

In this specification, the phrase “at least one of” as used in this disclosure means “one or more” of desired choices. As one example, the phrase “at least one of” as used in this disclosure includes “only one of the two choices” and “both of the two choices” in a case where the number of choices is two. In another example, the phrase “at least one of” means “only one of the choices” or “any combination of two or more of the choices” if the number of choices is three or more.

In this specification, phrases such as “the length (dimension) of A is equal to the length (dimension) of B” and “A and B are equal in length (dimension)” encompass a relationship in which a difference between the length (dimension) of A and the length (dimension) of B is, for example, 10% of the length (dimension) of A or less.

### Embodiments

### Structure of Semiconductor Device

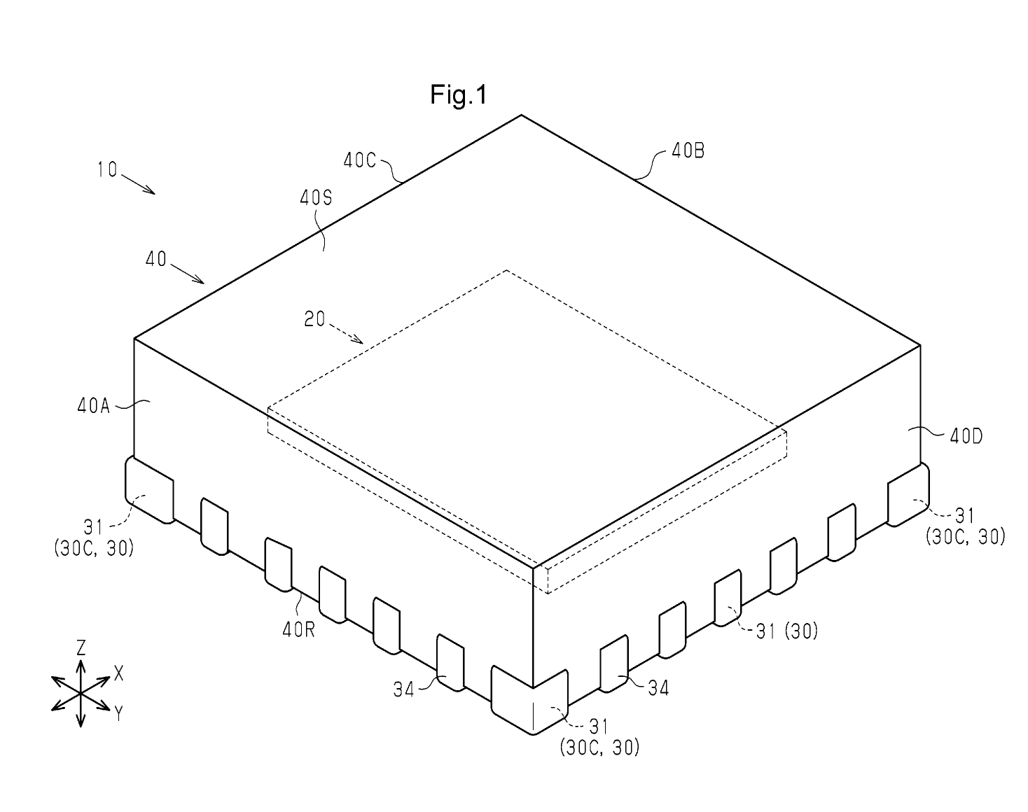

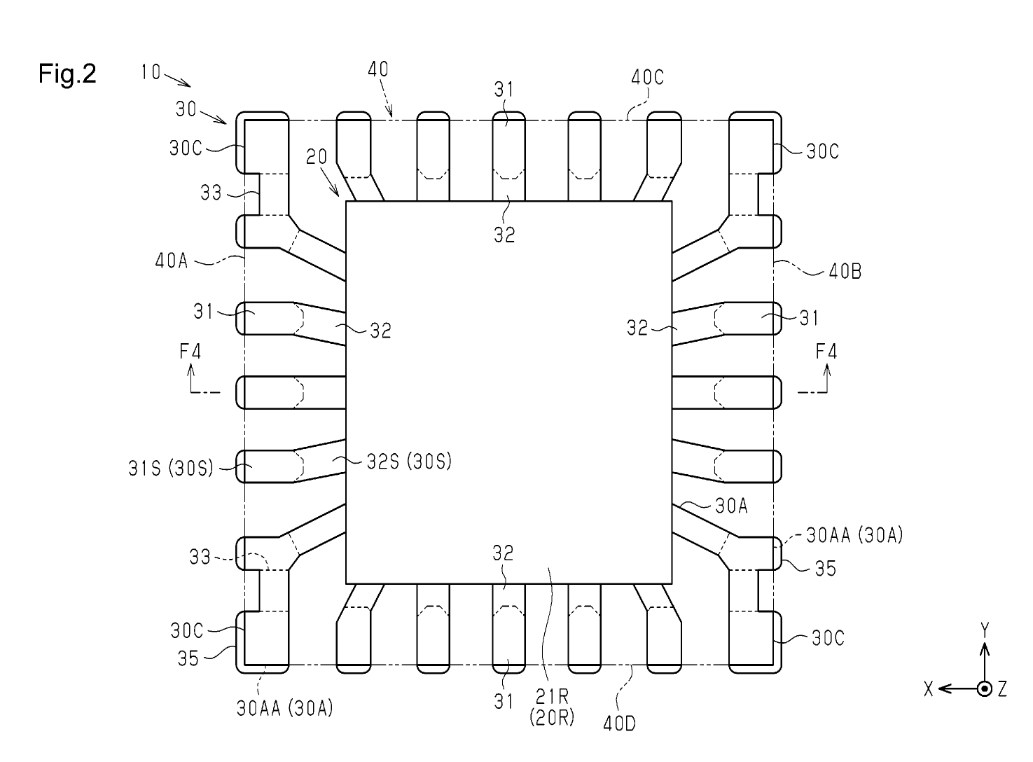

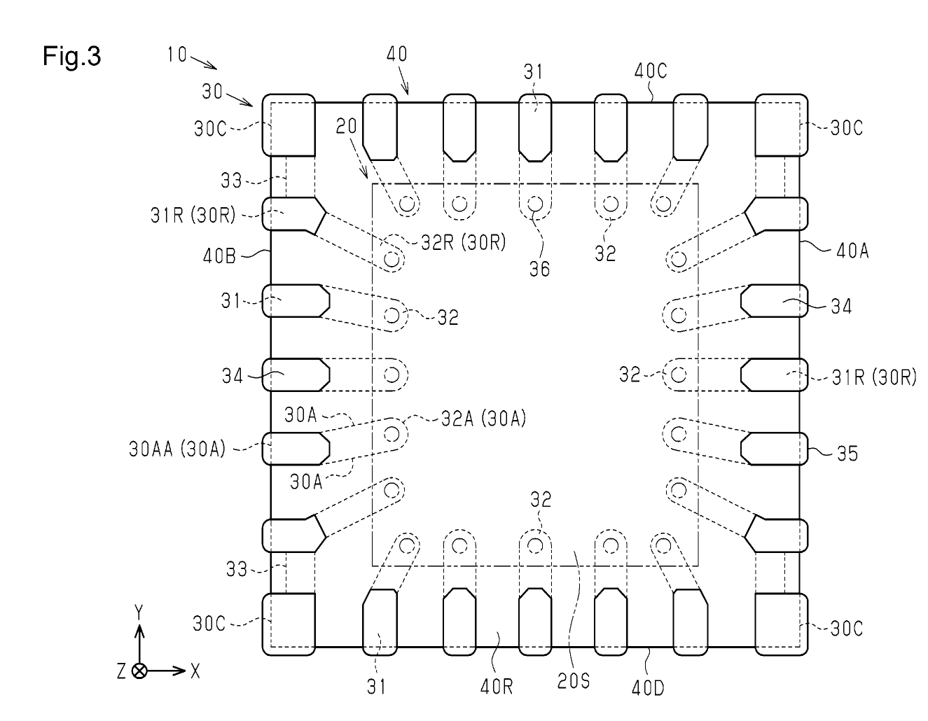

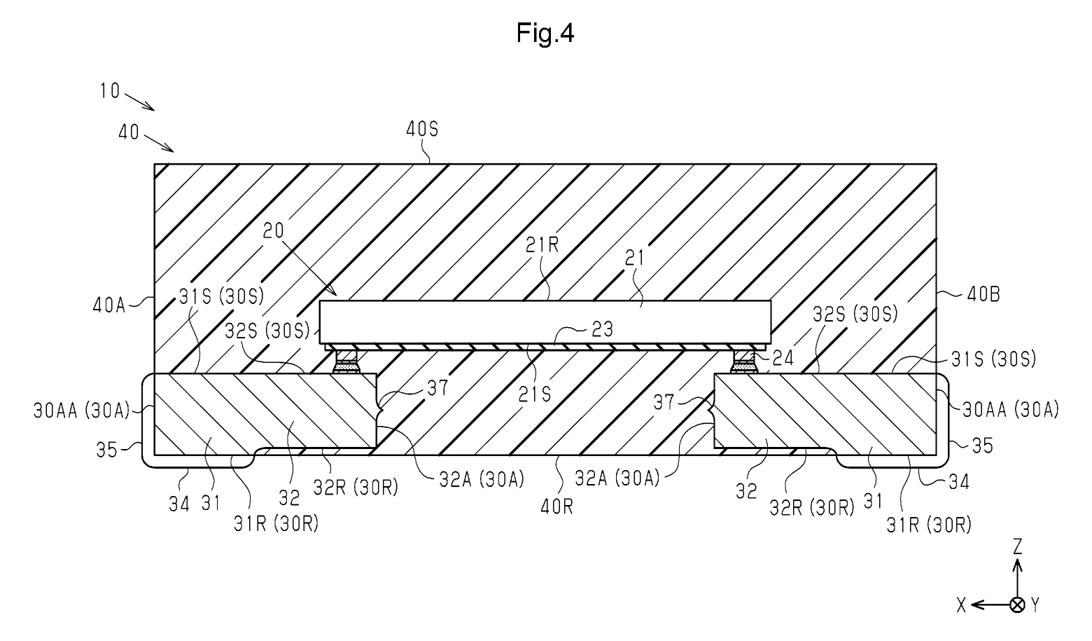

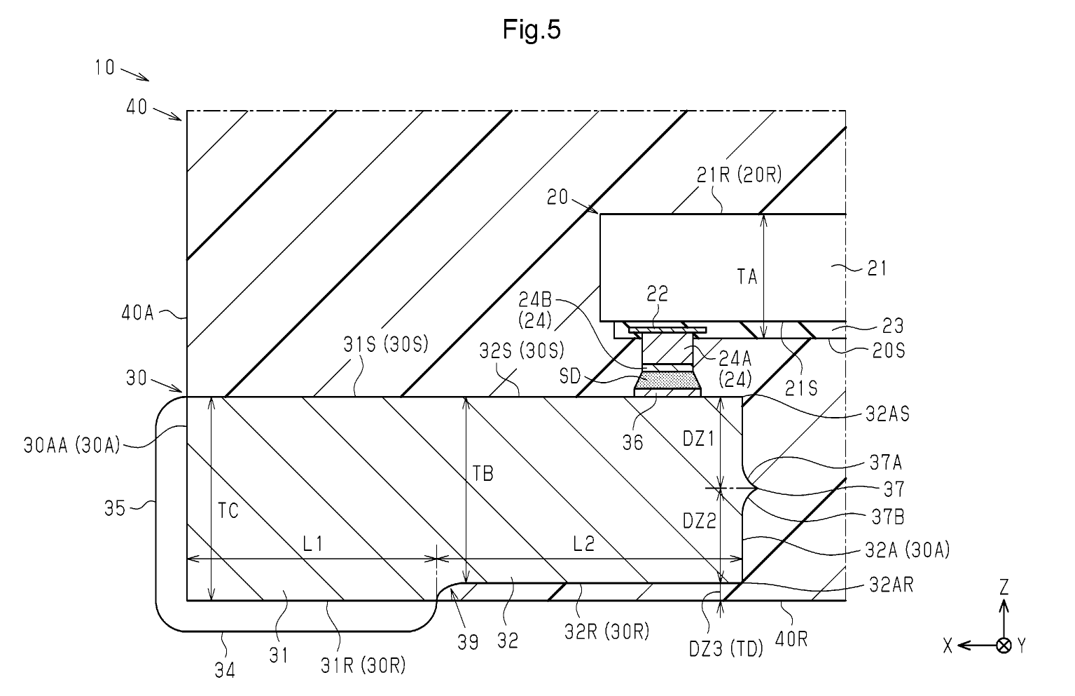

An overall structure of an embodiment of a semiconductor device 10 will now be described with reference to FIGS. 1 to 5. FIG. 1 is a schematic perspective view of the structure of the semiconductor device 10. FIG. 2 is a plan view schematically showing the internal structure of the semiconductor device 10. FIG. 3 is a schematic view showing the structure of a back surface of the semiconductor device 10. FIG. 4 is a schematic cross-sectional view showing the structure of the semiconductor device 10 taken along line F4-F4 in FIG. 2. FIG. 5 is an enlarged cross-sectional view showing a portion of the semiconductor device 10 in FIG. 4. In FIG. 1, the broken lines indicate a semiconductor chip 20, which will be described later. In FIG. 2, the double-dashed lines indicate an encapsulation resin 40, which will be described later. In FIG. 3, the double-dashed lines indicate the semiconductor chip 20. The X-axis, Y-axis, and Z-axis are orthogonal to one another as shown in FIG. 1. The term “plan view” as used in the present disclosure is a view of the semiconductor device 10 or the components of the semiconductor device 10 taken in the Z-direction.

As shown in FIGS. 1 and 4, the semiconductor device 10 includes the semiconductor chip 20, multiple terminals 30, and the encapsulation resin 40. The semiconductor chip 20 is mounted on the terminals 30. The encapsulation resin 40 encapsulates the semiconductor chip 20 and the terminals 30.

The encapsulation resin 40 defines a device head surface, a device back surface, and device side surfaces of the semiconductor device 10. The encapsulation resin 40 has the form of a rectangular plate having a thickness in the Z-direction. Therefore, the semiconductor device 10 has the form of a rectangular plate having a thickness in the Z-direction.

The encapsulation resin 40 includes an encapsulation head surface 40S and an encapsulation back surface 40R facing away from each other in the Z-direction, and first to fourth encapsulation side surfaces 40A to 40D connecting the encapsulation head surface 40S and the encapsulation back surface 40R. The encapsulation head surface 40S defines the device head surface. The encapsulation back surface 40R defines the device back surface. The first to fourth encapsulation side surfaces 40A to 40D define the device side surfaces. The first encapsulation side surface 40A and the second encapsulation side surface 40B define opposite end surfaces of the encapsulation resin 40 in the X-direction. The third encapsulation side surface 40C and the fourth encapsulation side surface 40D define opposite end surfaces of the encapsulation resin 40 in the Y-direction. The encapsulation resin 40 is formed from, for example, a black epoxy resin.

As shown in FIGS. 2 and 3, the terminals 30 are arranged along each of the first to fourth encapsulation side surfaces 40A to 40D in plan view. Each of the terminals 30 is partially exposed from the encapsulation resin 40. Each terminal 30 includes a back surface 30R partially exposed from the encapsulation back surface 40R of the encapsulation resin 40, a head surface 30S facing away from the back surface 30R, and side surfaces 30A connecting the head surface 30S and the back surface 30R. In the embodiment, the Z-direction conforms to a “thickness direction of the terminal 30”.

The terminal 30 includes a terminal portion 31 and a mount portion 32. In an example, the terminal portion 31 is integrated with the mount portion 32. In other words, the terminal portion 31 and the mount portion 32 are integrally formed from the same metal material. The terminal 30 is formed from a material including, for example, copper (Cu), aluminum (Al), or the like. In the embodiment, the terminal 30 is formed from a material including Cu. The terminal 30 is formed by etching a metal plate including Cu. In other words, the terminals 30 are formed of a metal lead frame.

As shown in FIG. 4, each terminal portion 31 includes a terminal back surface 31R at least partially exposed from the encapsulation back surface 40R of the encapsulation resin 40. In the embodiment, the entirety of the terminal back surface 31R is exposed from the encapsulation back surface 40R. The terminal back surface 31R is part of the back surface 30R. The terminal portion 31 includes a terminal head surface 31S facing away from the terminal back surface 31R. The terminal head surface 31S is part of the head surface 30S. The terminal portions 31 of the terminals 30 are located toward the first to fourth encapsulation side surfaces 40A to 40D from the semiconductor chip 20 in plan view. Thus, the terminal portions 31 of the terminals 30 are located outward from the semiconductor chip 20 in plan view. As described above, the semiconductor device 10 has a structure of a fanout package.

The terminal portions 31 of the terminals 30 are arranged along the first to fourth encapsulation side surfaces 40A to 40D in plan view. Each terminal portion 31 includes an exposed side surface 30AA that is flush with one of the first to fourth encapsulation side surfaces 40A to 40D and exposed from the one of the first to fourth encapsulation side surfaces 40A to 40D. The exposed side surface 30AA is part of the side surface 30A of the terminal 30.

A back plating layer 34 is formed on the terminal back surfaces 31R of the terminals 30. The back plating layer 34 is an example of a “back conductive film.” The back plating layer 34 projects from the encapsulation back surface 40R. A side plating layer 35 is formed on the exposed side surfaces 30AA of the terminals 30. The side plating layer 35 is an example of a “side conductive film.” The side plating layer 35 projects from the first to fourth encapsulation side surfaces 40A to 40D. In the embodiment, the back plating layer 34 is integrated with the side plating layer 35. The back plating layer 34 and the side plating layer 35 include, for example, at least one of gold (Au), nickel (Ni), tin (Sn), and palladium (Pd).

The mount portion 32 is disposed in the encapsulation resin 40. The mount portion 32 extends from the terminal portion 31 in a direction intersecting the Z-direction. In an example, the mount portion 32 extends from the terminal portion 31 in a direction orthogonal to the Z-direction. Hereinafter, a direction in which the mount portion 32 extends in plan view is referred to as a “first direction.” In FIG. 4, the first direction conforms to the X-direction. The mount portion 32 extends from the terminal portion 31 toward the semiconductor chip 20 in plan view. The mount portion 32 includes a part overlapping the semiconductor chip 20 in plan view. The mount portion 32 includes an end surface 32A, which is one of the side surfaces 30A located at an end in the first direction in the encapsulation resin.

The mount portion 32 includes a mount head surface 32S, which is part of the head surface 30S corresponding to the mount portion 32. In an example, the mount head surface 32S is flush with the terminal head surface 31S of the terminal portion 31. The mount portion 32 includes a mount back surface 32R, which is part of the back surface 30R corresponding to the mount portion 32. The mount back surface 32R is located closer to the encapsulation head surface 40S than the terminal back surface 31R of the terminal portion 31 is. The mount back surface 32R is covered by the encapsulation resin 40.

As shown in FIG. 5, the mount head surface 32S and the mount back surface 32R of the mount portion 32 are planes intersecting the Z-direction. In the example shown in FIG. 5, the mount head surface 32S is a plane orthogonal to the Z-direction.

As shown in FIG. 2, of the terminals 30, terminals 30 (hereinafter referred to as “corner terminals 30C”) disposed at four corners of the encapsulation resin 40 in plan view each include two terminal portions 31. The two terminal portions 31 of each corner terminal 30C are located at the same position in the X-direction and separated from each other in the Y-direction. The terminal portions 31 are joined by a terminal joint 33.

As shown in FIGS. 2 to 4, the semiconductor chip 20 is mounted on the mount portion 32 of each terminal 30. The semiconductor chip 20 has the form of a rectangular plate having a thickness in the Z-direction. The semiconductor chip 20 includes a semiconductor substrate 21 forming a chip body. The semiconductor substrate 21 is formed from a material including, for example, silicon (Si). The semiconductor chip 20 is, for example, a large scale integration (LSI). The semiconductor chip 20 includes a chip head surface 20S and a chip back surface 20R facing away from each other in the Z-direction. The chip head surface 20S faces the same direction as the encapsulation back surface 40R of the encapsulation resin 40. That is, the chip head surface 20S faces the mount head surface 32S of the mount portion 32. The chip back surface 20R faces the same direction as the encapsulation head surface 40S of the encapsulation resin 40.

As shown in FIG. 4, the semiconductor substrate 21 includes a body head surface 21S and a body back surface 21R facing away from each other in the Z-direction. The body head surface 21S faces the same direction as the chip head surface 20S of the semiconductor chip 20. The body back surface 21R faces the same direction as the chip back surface 20R. In the example shown in FIG. 4, the body back surface 21R is the chip back surface 20R.

As shown in FIG. 5, the semiconductor chip 20 includes multiple interconnects 22 disposed on the body head surface 21S of the semiconductor substrate 21 and an insulation layer 23 covering the body head surface 21S. The interconnects 22 are arranged on the semiconductor substrate 21 so as to face the mount portions 32 of the terminals 30 in the Z-direction. The insulation layer 23 has openings separately exposing the interconnects 22 in the Z-direction. The interconnects 22 are formed from a material including, for example, at least one of aluminum (Al), Cu, Au, titanium (Ti).

The semiconductor chip 20 includes multiple chip terminals 24 formed on the chip head surface 20S. The chip terminals 24 are separately bonded to the interconnects 22. The chip terminals 24 each have the form of, for example, a cylindrical post extending in the Z-direction. The chip terminals 24 are bonded to the interconnects 22 exposed from the openings in the insulation layer 23.

As shown in FIG. 5, each chip terminal 24 includes a terminal body 24A having the form of a cylindrical post and a barrier layer 24B disposed on a distal end surface of the terminal body 24A. The chip terminal 24 includes, for example, at least one of Cu, Al, and Ti. The barrier layer 24B is, for example, a plating layer. The barrier layer 24B includes at least one of Au, Ni, and Pd. In an example, the barrier layer 24B is formed from a material including Ni.

A barrier layer 36 is disposed on the mount head surface 32S of the mount portion 32 of each terminal 30 in a region where the chip terminal 24 is connected. In other words, the region where the chip terminal 24 is connected is a region on which the semiconductor chip 20 is mounted. The barrier layer 36 defines part of the mount head surface 32S. In an example, the barrier layer 36 is circular in plan view (refer to FIG. 3). The shape of the barrier layer 36 in plan view may be changed in any manner. The barrier layer 36 includes, for example, at least one of Ni and Ti.

The barrier layer 24B of each chip terminal 24 is bonded to the barrier layer 36 of the mount portion 32 corresponding to the barrier layer 24B by a conductive bonding material SD. Thus, the semiconductor chip 20 is mounted on the mount portions 32. The barrier layer 36 limits a decrease in the wettability of the conductive bonding material SD. As described above, the chip terminals 24 are electrically connected to the mount portions 32 of the terminals 30. The conductive bonding material SD may be, for example, silver (Ag) paste or solder paste.

### Terminal

The shape of the terminals 30 will be described in detail with reference to FIG. 5.

As shown in FIG. 5, each terminal 30 includes a projection 37. The projection 37 is, for example, located at an intermediate part of the end surface 32A in the Z-direction. The phrase “intermediate part” refers to a region between opposite ends of the end surface 32A in the Z-direction. More specifically, the mount portion 32 includes a head-side edge 32AS, which is an edge of the terminal 30 in the Z-direction at the head surface 30S, and a back-side edge 32AR, which is an edge of the terminal 30 in the Z-direction at the back surface 30R. The intermediate part is a region of the end surface 32A between the head-side edge 32AS and the back-side edge 32AR in the Z-direction. In the embodiment, the projection 37 is located at a central part of the end surface 32A in the Z-direction. It is determined that the projection 37 is located at the central part of the end surface 32A in the Z-direction when a difference between a distance DZ1 from the mount head surface 32S to the projection 37 in the Z-direction and a distance DZ2 from the mount back surface 32R to the projection 37 in the Z-direction is, for example, in 10% of the distance DZ1 between the mount head surface 32S and the projection 37 (or the distance DZ2 between the mount back surface 32R and the projection 37).

In the embodiment, the projection 37 is formed on the entirety of the end surface 32A in a width direction (in FIG. 5, the Y-direction) that is orthogonal to a direction in which the mount portion 32 extends in plan view. Hereinafter, the direction orthogonal to the direction in which the mount portion 32 extends in plan view is referred to as a “second direction.” Although not shown, projections 37 are formed on the side surfaces 30A located at opposite sides of the terminal 30 in the width direction (second direction). In an example, a projection 37 that is formed on the end surface 32A is integrated with projections 37 that are formed on the side surfaces 30A at opposite sides of the terminal 30 in the width direction (second direction). The projection 37 includes two side surfaces 37A and 37B oriented oppositely in the Z-direction. The side surfaces 37A and 37B are located next to each other in the Z-direction. The side surfaces 37A and 37B each include a curved surface. The curved surfaces are curved so as to approach each other toward a distal end of the projection 37.

As shown in FIG. 5, a thickness TB of the mount portion 32 is greater than a thickness TA of the semiconductor chip 20. In an example, a ratio of the thickness TB of the mount portion 32 to the thickness TA of the semiconductor chip 20 is greater than 1 and less than or equal to 1.8. In an example, the thickness TA of the semiconductor chip 20 is approximately 100 μm. In an example, the thickness TB of the mount portion 32 is approximately 180 μm. The thickness TB of the mount portion 32 is defined by the distance between the mount head surface 32S and the mount back surface 32R in the Z-direction. The thickness TA of the semiconductor chip 20 is defined by the distance between the chip head surface 20S and the chip back surface 20R in the Z-direction.

The thickness TB of the mount portion 32 is less than a thickness TC of the terminal portion 31. In an example, the ratio of the thickness TB of the mount portion 32 to the thickness TC of the terminal portion 31 is greater than 1/2. In an example, the ratio of the thickness TB of the mount portion 32 to the thickness TC of the terminal portion 31 is less than or equal to 4/5. A length L2 of the mount portion 32 in the first direction is greater than a length L1 of the terminal portion 31 in the first direction. The thickness TC of the terminal portion 31 is defined by the distance between the terminal back surface 31R and the terminal head surface 31S in the Z-direction.

The terminals 30 each include a step 39. The step 39 is formed so that the mount back surface 32R, which is part of the back surface 30R corresponding to the mount portion 32, is located closer to the head surface 30S than the terminal back surface 31R of the terminal portion 31 is. The step 39 is formed between the mount portion 32 and the terminal portion 31. In the embodiment, the step 39 connects the terminal back surface 31R and the mount back surface 32R. The step 39 includes a curved surface. In the embodiment, the step 39 is formed of the curved surface.

A dimension DZ3 of the step 39 in the thickness direction (the Z-direction) is less than the thickness TB of the mount portion 32. The dimension DZ3 of the step 39 in the thickness direction is defined by the distance between the terminal back surface 31R and the mount back surface 32R in the Z-direction. In an example, the dimension DZ3 of the step 39 in the thickness direction is equal to a thickness TD of a portion of the encapsulation resin 40 covering the mount back surface 32R. The thickness TD of the portion of the encapsulation resin 40 covering the mount back surface 32R is less than 1/2 of the thickness TB of the mount portion 32.

In an example, the dimension DZ3 of the step 39 in the thickness direction (the Z-direction) is less than the distance DZ2 between the mount back surface 32R and the projection 37 in the Z-direction. In an example, the dimension DZ3 of the step 39 in the thickness direction is less than the distance DZ1 between the mount head surface 32S and the projection 37.

### Method for Manufacturing Semiconductor Device

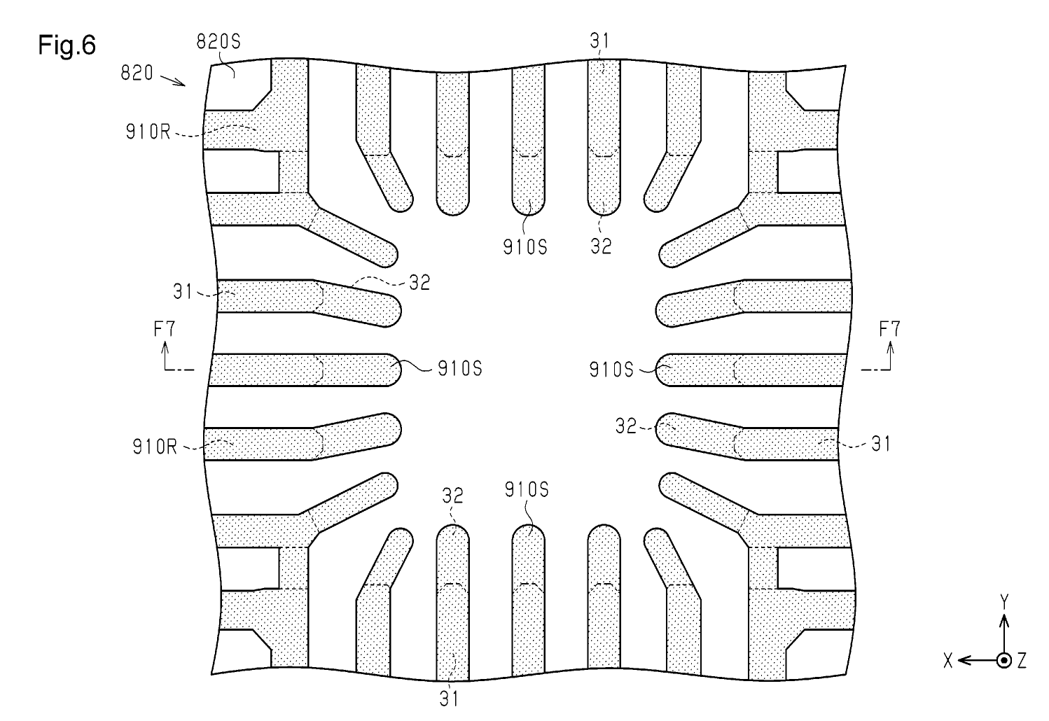

An example of a method for manufacturing the semiconductor device 10 will now be described with reference to FIGS. 6 to 13.

The method for manufacturing the semiconductor device 10 includes a step of preparing the terminals 30, a step of mounting the semiconductor chip 20 on the terminals 30, a step of cleaning the terminals 30 and the semiconductor chip 20, a step of forming the encapsulation resin 40, and a singulating step.

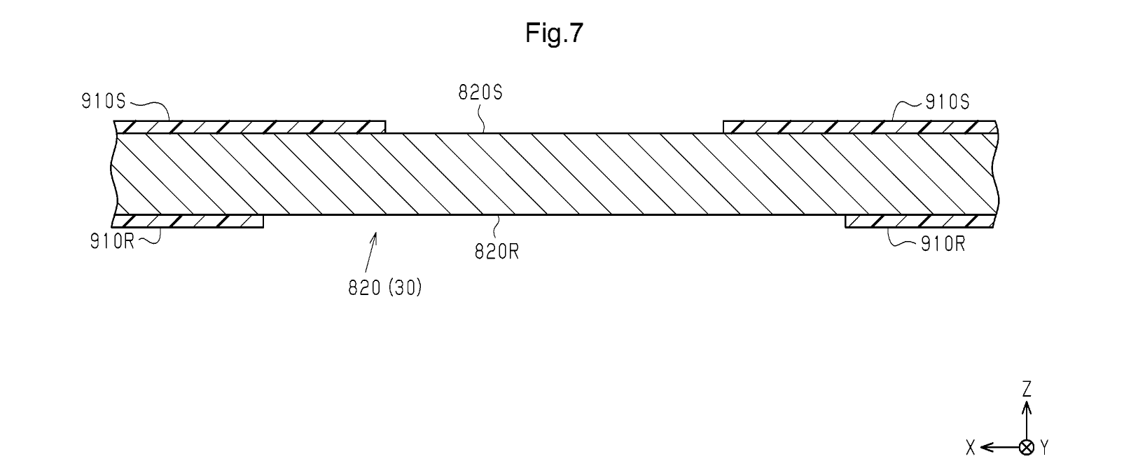

FIGS. 6 to 10 show examples of the step of preparing the terminals 30. FIG. 6 schematically shows the planar structure of a portion of a metal plate 820. In FIG. 6, the broken line indicates the boundary between the terminal portion 31 and the mount portion 32 in plan view. In FIG. 6, to facilitate the understanding of the drawing, a head-side resist 910S and a back-side resist 910R are provided with dots and will be described later. FIGS. 7 to 10 schematically show a structure of an end surface of a portion of the metal plate 820. In FIGS. 7 to 10, the position of the end surface is indicated by line F7-F7 in FIG. 6,

As shown in FIGS. 6 and 7, in the step of preparing the terminals 30, a metal plate 820 is prepared. The metal plate 820 is flat and has a thickness in the Z-direction. The metal plate 820 is formed from, for example, a material including Cu. The metal plate 820 includes a head surface 820S and a back surface 820R facing away from each other in the Z-direction.

Then, the head-side resist 910S is formed on the head surface 820S of the metal plate 820. As shown in FIG. 6, the head-side resist 910S covers a portion of the head surface 820S of the metal plate 820 corresponding to the terminal portion 31 and the mount portion 32. As shown in FIG. 7, the back-side resist 910R is formed on the back surface 820R of the metal plate 820. The back-side resist 910R covers a portion of the back surface 820R of the metal plate 820 corresponding to the terminal portion 31 (refer to FIG. 6).

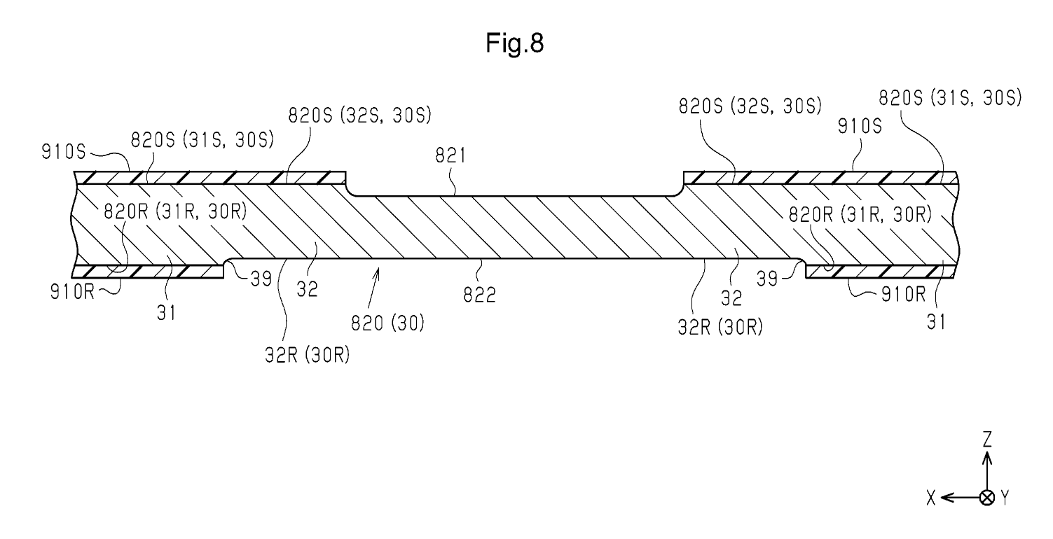

As shown in FIG. 8, the head surface 820S of the metal plate 820 is partially etched to form a recess 821. The recess 821 is formed in a portion of the head surface 820S of the metal plate 820 exposed from the head-side resist 910S. More specifically, a portion of the head surface 820S of the metal plate 820 that differs from the terminals 30 is etched. This forms the recess 821 in the head surface 820S of the metal plate 820.

Also, the back surface 820R of the metal plate 820 is etched to form a recess 822. The recess 822 is formed in a portion of the back surface 820R of the metal plate 820 exposed from the back-side resist 910R. This forms the mount back surface 32R of the mount portion 32. In addition, the step 39 is formed between the mount portion 32 and the terminal portion 31 at a position closer to the head surface 30S than the terminal back surface 31R of the terminal portion 31 is.

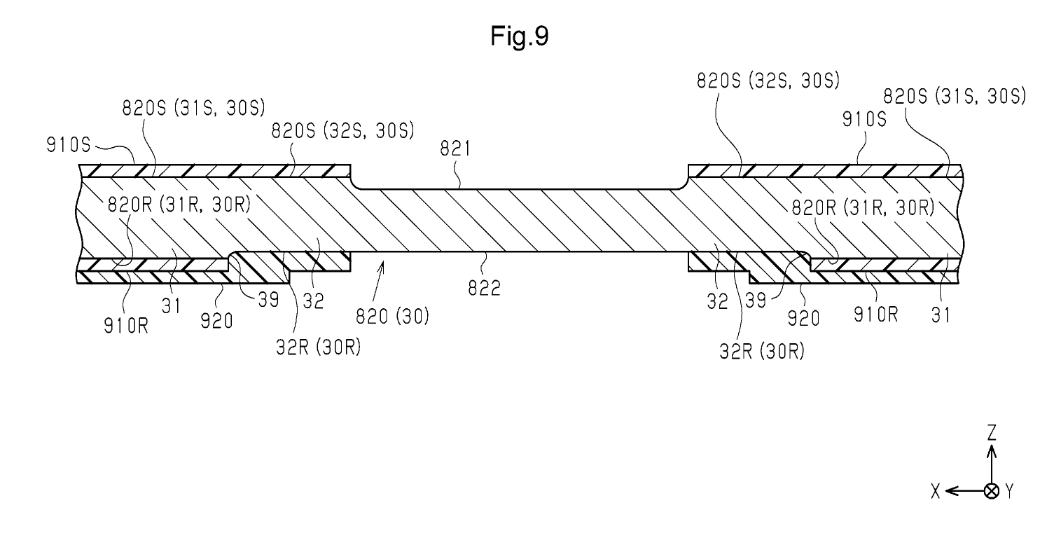

As shown in FIG. 9, a back-side resist 920 is formed on the back surface 820R of the metal plate 820. The back-side resist 920 covers the back-side resist 910R and a portion of the back surface 820R of the metal plate 820 corresponding to the mount back surface 32R. That is, the back-side resist 920 covers a portion of the recess 822. In addition, in the same manner as the head-side resist 910S, the back-side resist 920 exposes a portion of the back surface 820R of the metal plate 820 that differs from the terminals 30.

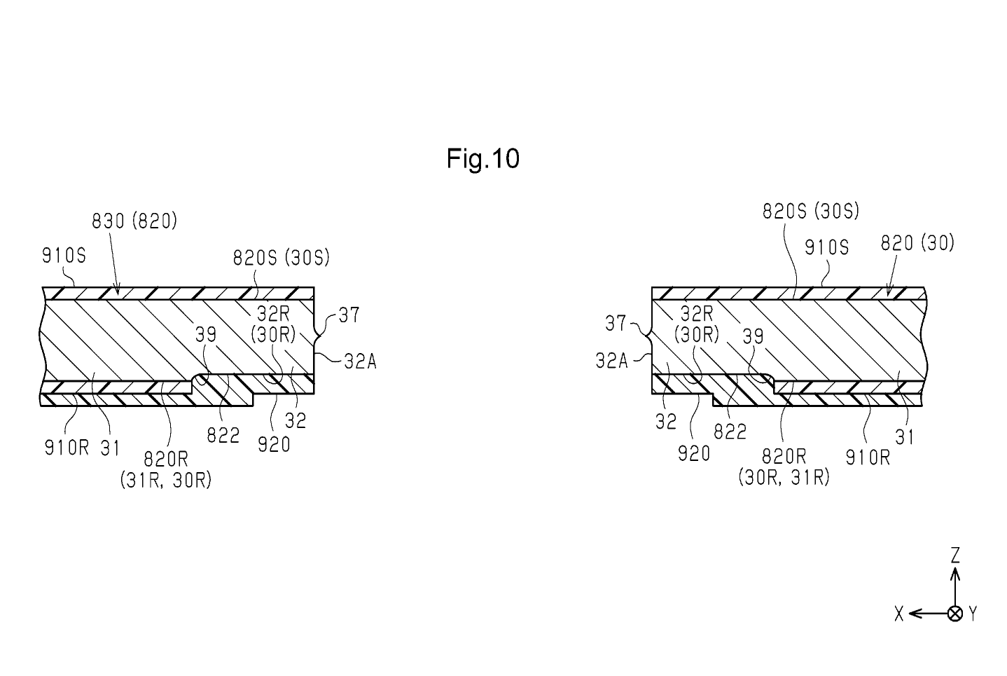

As shown in FIG. 10, etching is performed on the recess 821 from the head surface 820S of the metal plate 820 and on the recess 822 from the back surface 820R of the metal plate 820. In this step, portions of the metal plate 820 differing from the terminals 30 are removed so that the terminal portion 31 and the mount portion 32 are formed. Also, the end surface 32A, which is an end surface of the terminal 30 in the first direction orthogonal to the thickness direction (the Z-direction), and the projection 37, which is located at an intermediate part of the end surface 32A in the Z-direction, are formed. In the embodiment, the amount of etching from the head surface 820S of the metal plate 820 in the Z-direction is equal to the amount of etching from the back surface 820R of the metal plate 820 in the Z-direction. Therefore, the projection 37 is formed at a central part of the end surface 32A in the Z-direction.

Subsequently, the head-side resist 910S and the back-side resists 910R and 920 are removed. The steps described above form a lead frame 830 including the terminal portions 31 and the mount portions 32 of the terminals 30.

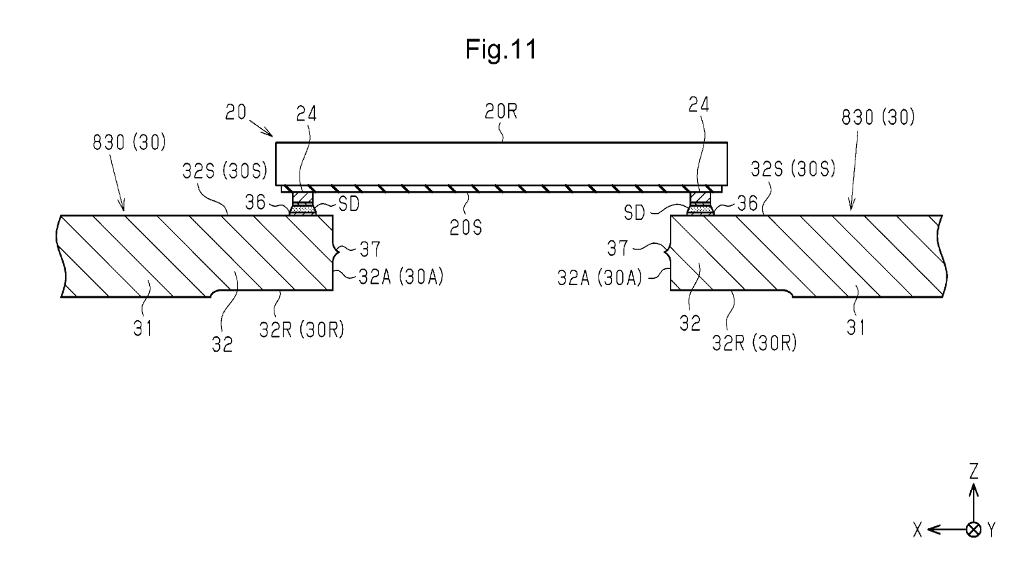

FIG. 11 shows an example of a step of mounting the semiconductor chip 20 on the lead frame 830. In the step of mounting the semiconductor chip 20 on the lead frame 830, the chip terminals 24 of the semiconductor chip 20 are arranged on the lead frame 830. More specifically, the barrier layer 36 is formed on the mount head surfaces 32S of the terminals 30 in the lead frame 830. Subsequently, a layer of the conductive bonding material SD is formed on the barrier layer 36. Alternatively, the conductive bonding material SD may be formed on the chip terminals 24 of the semiconductor chip 20. Alternatively, the conductive bonding material SD may be formed on both the barrier layer 36 and the chip terminals 24. In an example, when solder paste is used as the conductive bonding material SD, flux is applied. The chip terminals 24 of the semiconductor chip 20 are placed on the conductive bonding material SD formed on the barrier layer 36 on the mount head surfaces 32S of the terminals 30 of the lead frame 830. Subsequently, the conductive bonding material SD is, for example, melted and then solidified through a reflow process. As a result, the chip terminals 24 are bonded to the lead frame 830. Thus, the chip terminals 24 are electrically connected to the lead frame 830.

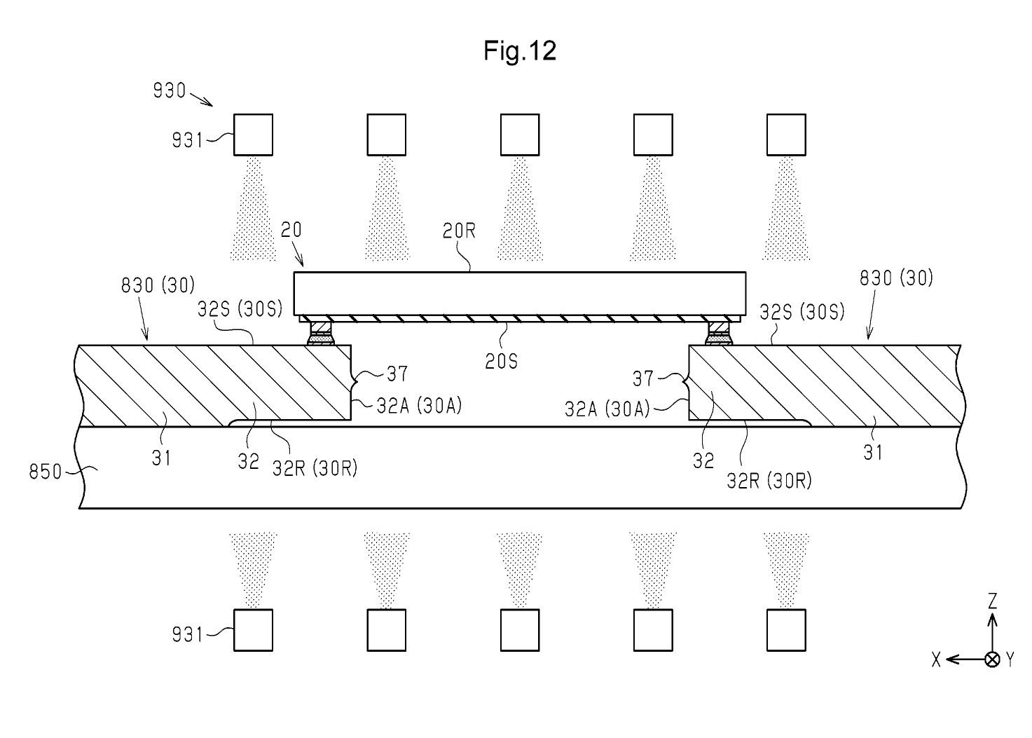

FIG. 12 shows a step of cleaning the semiconductor chip 20 mounted on the lead frame 830. The cleaning step, for example, cleans the semiconductor chip 20 and the lead frame 830 and removes residues such as the flux. In an example, the cleaning step includes spray cleaning.

More specifically, a support substrate 850 supports the lead frame 830 on which the semiconductor chip 20 is mounted. The support substrate 850 is transported to a cleaning device 930, for example. The cleaning device 930 includes spray nozzles 931. Each spray nozzle 931 is configured to spray pure water and a chemical agent onto the semiconductor chip 20 and the lead frame 830. As a result, foreign matter and contaminants are cleaned and removed from the semiconductor chip 20 and the lead frame 830.

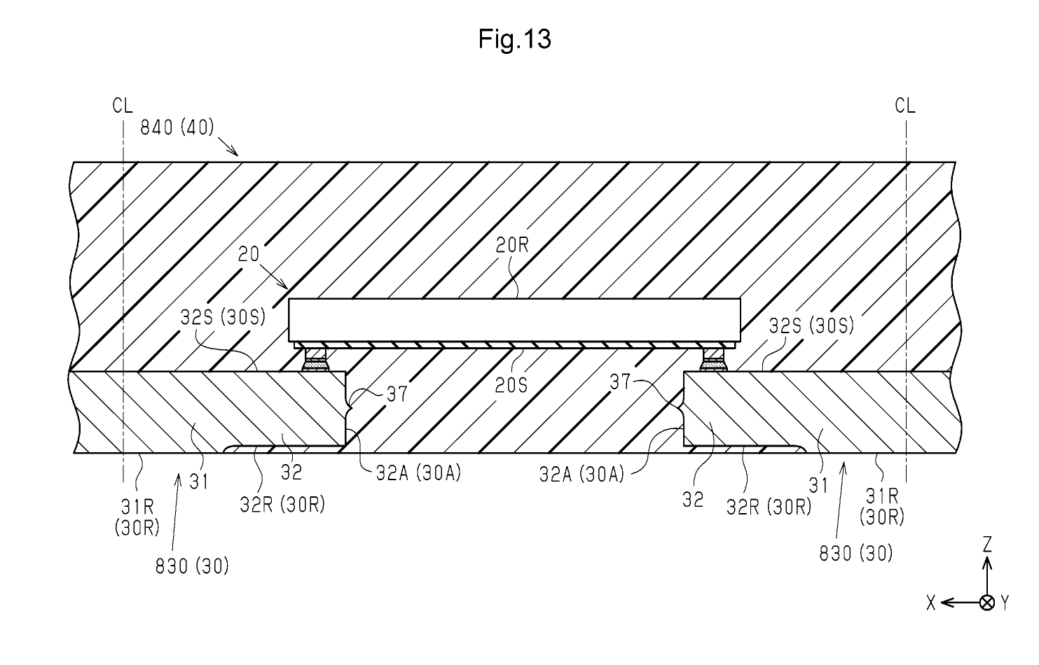

FIG. 13 shows a step of forming the encapsulation resin 40 and a singulating step. FIG. 13 schematically shows a cross-sectional view of a portion of the lead frame 830, the semiconductor chip 20, and a resin layer 840, which will be described later.

In the step of forming the encapsulation resin 40, the resin layer 840 is formed by, for example, transfer molding to cover the semiconductor chip 20 and the lead frame 830. The resin layer 840 includes multiple pieces of the encapsulation resin 40.

In the singulating step, the resin layer 840 and the lead frame 830 are cut by, for example, dicing along cutting lines CL shown in FIG. 13. This forms multiple pieces of the encapsulation resin 40 and the terminals 30. The exposed side surfaces 30AA (refer to FIG. 4) of the terminals 30 are exposed from the first to fourth encapsulation side surfaces 40A to 40D (refer to FIG. 2) of the encapsulation resin 40.

Next, although not shown, the method for manufacturing the semiconductor device 10 includes a step of forming the back plating layer 34 and the side plating layer 35 (refer to FIG. 4). The back plating layer 34 and the side plating layer 35 are formed by, for example, electroless plating. As a result, the back plating layer 34 and the side plating layer 35 are formed on the terminal back surfaces 31R and the exposed side surfaces 30AA (refer to FIG. 4) of the terminals 30 exposed from the encapsulation resin 40. The steps described above manufacture the semiconductor device 10.

### Operation of Embodiment

The operation of the semiconductor device 10 of the embodiment will now be described.

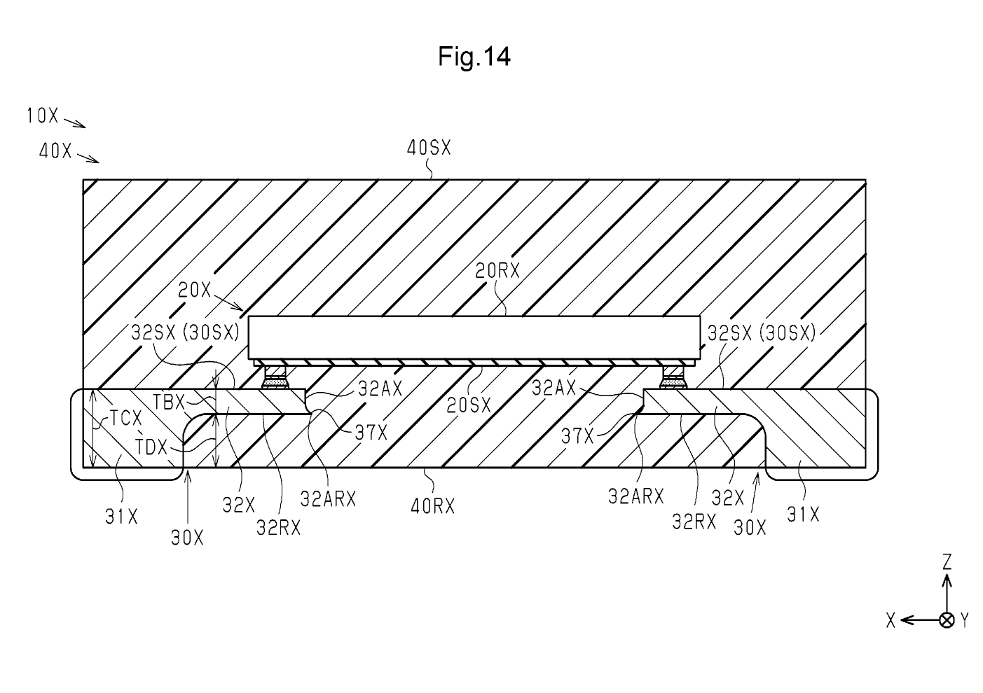

First, a comparative example of a semiconductor device 10X will be described with reference to FIG. 14. FIG. 14 schematically shows a cross-sectional structure of the semiconductor device 10X of the comparative example. The position of the cross section in FIG. 14 is the same as the position of the cross section of the semiconductor device 10 shown in FIG. 4. In the semiconductor device 10 of the comparative example, components corresponding to those of the semiconductor device 10 of the embodiment are designated by adding the letter “X” to the reference numerals of the components of the semiconductor device 10.

As shown in FIG. 14, the semiconductor device 10X of the comparative example differs from the semiconductor device 10 of the embodiment in the structure of the terminals 30X. More specifically, the thickness TBX of the mount portion 32X in the semiconductor device 10X of the comparative example is less than the thickness TB of the mount portion 32 (refer to FIG. 5) in the semiconductor device 10 of the embodiment. Accordingly, the thickness TDX of a portion of the encapsulation resin 40X covering the mount back surface 32RX of the mount portion 32X in the comparative example is greater than the thickness TD (refer to FIG. 5) of the portion of the encapsulation resin 40 covering the mount back surface 32R in the embodiment. The projection 37X is located on the back-side edge 32ARX of the mount portion 32X in the Z-direction. The projection 37X includes a curved surface toward the mount head surface 32SX and a flat surface at the mount back surface 32RX. The flat surface extends in a direction orthogonal to the Z-direction. The projection 37X differs in shape and position in the Z-direction due to the manufacturing method being different from that of the semiconductor device 10 of the embodiment.

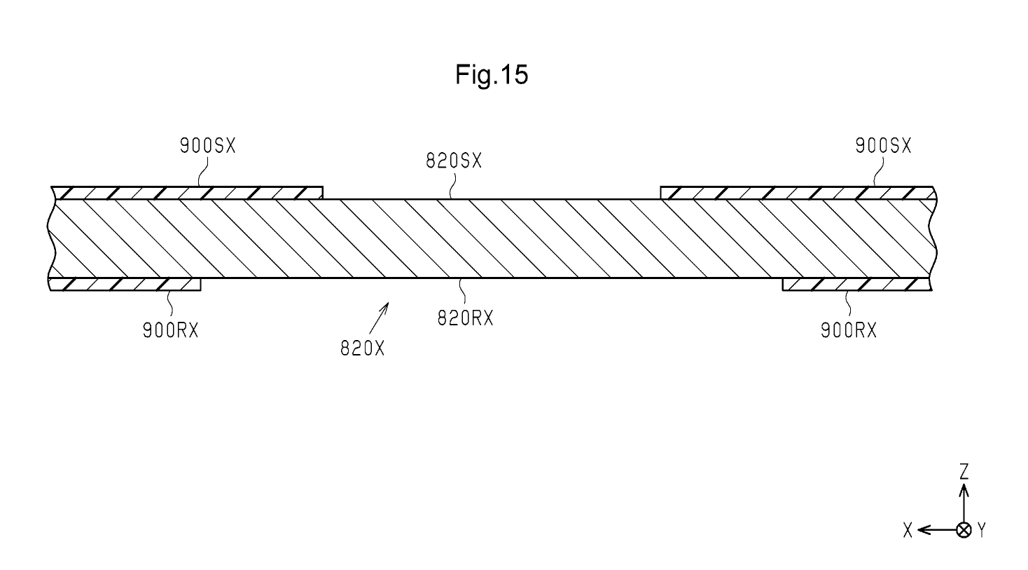

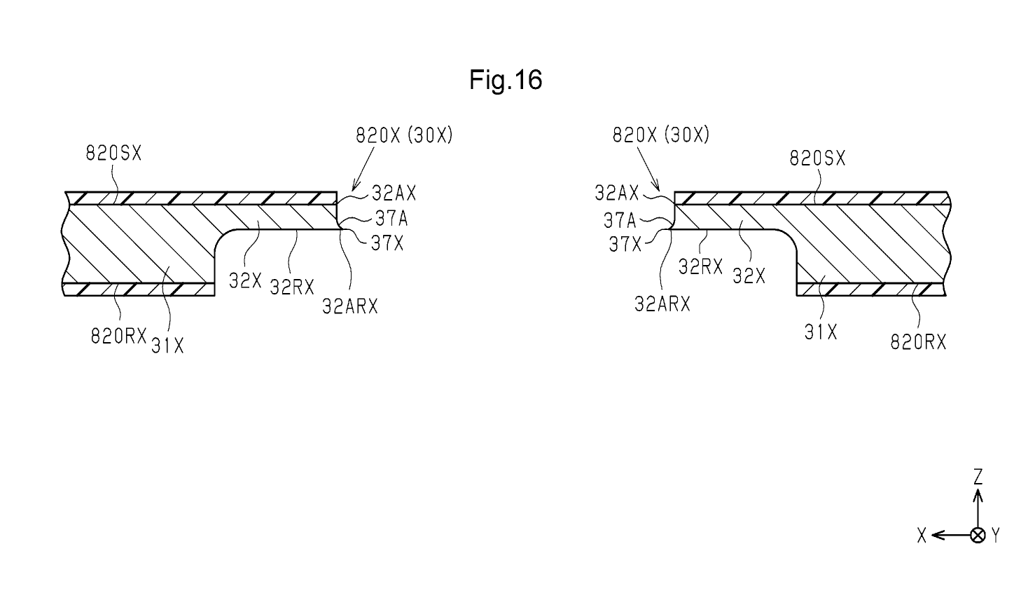

A method for manufacturing the terminals 30X of the semiconductor device 10X in the comparative example will be described below with reference to FIGS. 15 and 16. FIGS. 15 and 16 each show part of a step of forming the lead frame 830X including the terminals 30X from the metal plate 820X of the semiconductor device 10X in the comparative example. The position of the end surface shown in FIGS. 15 and 16 is the same as the position of the cross section shown in FIG. 14.

As shown in FIG. 15, the head-side resist 900SX is formed on the head surface 820SX of the metal plate 820X, and the back-side resist 900RX is formed on the back surface 820RX of the metal plate 820X. The head-side resist 900SX may be identical in shape to the head-side resist 910S formed on the head surface 820S of the embodiment. The back-side resist 900RX may be identical in shape to the back-side resist 910R formed on the back surface 820R of the embodiment.

As shown in FIG. 16, etching is performed from both the head surface 820S and the back surface 820RX of the metal plate 820X. As a result, a portion of the metal plate 820X differing from the terminals 30 is removed. More specifically, first, the first the metal plate 820X is half-etched from the back surface 820RX. This forms the mount back surface 32RX and the terminal portion 31X. Next, the metal plate 820X is etched from the head surface 820SX. This removes a portion of the metal plate 820X differing from the terminals 30 and forms the mount portion 32X. Also, the end surface 32AX, which is an end surface of the terminal 30 in the first direction orthogonal to the thickness direction, and the projection 37X, which is located on the back-side edge 32ARX of the end surface 32AX, are formed. Thus, in the semiconductor device 10X of the comparative example, the projection 37X is located on the back-side edge 32ARX.

For example, when a temperature cycle test is conducted, stress tends to concentrate on edges, in the Z-direction, of a distal end of the mount portion of each terminal due to a difference in linear expansion coefficients between the encapsulation resin and the edges. In the semiconductor device 10X of the comparative example, the projection 37X is located on the back-side edge 32ARX of the mount portion 32X of each terminal 30X. This further concentrates stress. Concentration of stress may cause formation of cracks in the encapsulation resin 40 and separation of the encapsulation resin 40 from the terminal 30X.

In the semiconductor device 10 of the embodiment, the projection 37 is formed at the intermediate part of the end surface 32A of the mount portion 32 in the Z-direction. Therefore, stress is less likely to concentrate on the back-side edge 32AR of the end surface 32A of the mount portion 32 than the structure of the comparative example.

In the semiconductor device 10X of the comparative example, the back surface 820RX of the metal plate 820 is removed by half-etching. Thus, the thickness TBX of the mount portion 32X is approximately 1/2 of the thickness TCX of the terminal portion 31X. In the semiconductor device 10X of the comparative example, in the step of cleaning the terminals 30X and the semiconductor chip 20, the sprayed pure water and chemical agent cause the mount portion 32X to oscillate in the Z-direction. This may apply force to the conductive bonding material SD that bonds the mount portion 32X to the chip terminals 24 of the semiconductor chip 20 and may crack or remove the conductive bonding material SD. As a result, the electrical connection between the mount portion 32X and the chip terminals 24 may become unstable.

In this regard, in the semiconductor device 10 of the embodiment, the thickness TB of the mount portions 32 of the terminals 30 is greater than 1/2 of the thickness TC of the terminal portion 31. More specifically, the thickness TB of the mount portion 32 is greater than the thickness TBX of the mount portion 32X in the semiconductor device 10X of the comparative example. Therefore, in the step of cleaning the terminals 30 and the semiconductor chip 20, oscillation of the mount portion 32 in the Z-direction caused by the sprayed pure water and chemical agent is limited. This limits the force applied to the conductive bonding material SD, which bonds the mount portion 32 to the chip terminals 24, thereby limiting cracks and removal of the conductive bonding material SD. As a result, the mount portion 32 and the chip terminals 24 are stably electrically connected.

### Advantages of Embodiment

The semiconductor device 10 of the embodiment has the following advantages.

(1) The semiconductor device 10 includes the terminals 30, the semiconductor chip 20 mounted on the terminals 30, and the encapsulation resin 40 encapsulating the terminals 30 and the semiconductor chip 20. The terminals 30 each include the back surface 30R at least partially exposed from the encapsulation resin 40, the head surface 30S on which the semiconductor chip 20 is mounted, the end surface 32A, which is an end surface in the X-direction orthogonal to the thickness direction (the Z-direction) of the terminals 30 disposed in the encapsulation resin 40, and the projection 37 located at an intermediate part of the end surface 32A in the Z-direction.

In this structure, the projection 37 is located at the intermediate part of the end surface 32A, rather than on the head-side edge 32AS or the back-side edge 32AR. This limits concentration of stress on one of the head-side edge 32AS and the back-side edge 32AR of the mount portion 32.

(2) The projection 37 is located at a central part of the end surface 32A of the mount portion 32 in the Z-direction.

With this structure, stress is less likely to concentrate on one of the head-side edge 32AS and the back-side edge 32AR of the end surface 32A than a structure in which the projection 37 is located toward one of the head-side edge 32AS and the back-side edge 32AR from the central part of the end surface 32A.

(3) The projection 37 extends on the entirety of the end surface 32A in the Y-direction.

With this structure, stress is less likely to concentrate on a portion of the end surface 32A than a structure in which the projection 37 is formed on only a portion of the end surface 32A in the Y-direction. In addition, the projection 37 restricts movement of the encapsulation resin 40 relative to the terminals 30 in the Z-direction. Thus, the terminals 30 are less likely to separate from the encapsulation resin 40.

(4) The projection 37 includes the two side surfaces 37A and 37B oriented oppositely with respect to the Z-direction. The side surfaces 37A and 37B each include a curved surface. The curved surfaces are curved so as to approach each other toward the distal end of the projection 37.

With this structure, the projection 37 exhibits a smoother variation in shape than a structure in which the projection 37 is, for example, rectangular. This limits concentration of stress on the projection 37. In addition, as compared to a structure in which one of the opposite side surfaces, in the Z-direction, of the projection 37 includes a flat surface orthogonal to the Z-direction, force is likely to be equally applied to the side surfaces 37A and 37B of the projection 37 in the Z-direction. This limits deformation of the terminals 30 in the Z-direction that occurs when force is differently applied to the side surfaces 37A and 37B of the projection 37 in the Z-direction.

(5) The terminals 30 each include the terminal portion 31 and the mount portion 32. The terminal portion 31 includes the terminal back surface 31R, which is part of the back surface 30R exposed from the encapsulation resin 40. The mount portion 32 extends in the encapsulation resin 40 from the terminal portion 31 in the first direction and includes the end surface 32A. The ratio of the thickness TB of the mount portion 32 to the thickness TC of the terminal portion 31 is greater than 1/2.

With this structure, deformation of the mount portion 32 caused by external force is limited as compared to a structure in which the ratio of the thickness TB of the mount portion 32 to the thickness TC of the terminal portion 31 is less than or equal to 1/2. For example, in the step (refer to FIG. 12) of cleaning the terminals 30, oscillation of the mount portion 32 that occurs when the terminals 30 receive pressure in the Z-direction is limited. As a result, the electrical connection between the mount portion 32 and the semiconductor chip 20 is stabilized.

In addition, the thickness TB of the mount portion 32 is greater than the thickness TBX of the mount portion 32X in the semiconductor device 10X of the comparative example. Thus, the electrical resistance of the terminals 30 is lower than that in the semiconductor device 10X of the comparative example, thereby allowing a large current to flow to the terminals 30.

(6) The part of the back surface 30R corresponding to the mount portion 32 includes the step 39 formed between the mount portion 32 and the terminal portion 31 at a position closer to the head surface 30S than the terminal back surface 31R of the terminal portion 31 is. The dimension DZ3 of the step 39 in the thickness direction (the Z-direction) is less than the thickness TB of the mount portion 32.

With this structure, the thickness TB of the mount portion 32 is increased as compared to a structure in which the dimension DZ3 of the step 39 in the thickness direction (the Z-direction) is greater than the thickness TB of the mount portion 32. This limits deformation of the mount portion 32.

(7) The step 39 includes a curved surface.

With this structure, concentration of stress on the step 39 is limited as compared to a structure in which the step 39 includes a flat surface. This limits deformation of the mount portion 32 caused by concentration of stress on the step 39.

(8) The dimension DZ3 of the step 39 in the thickness direction is less than the distance DZ2 between the mount back surface 32R of the mount portion 32 and the projection 37 in the Z-direction.

With this structure, the thickness TB of the mount portion 32 is increased as compared to a structure in which the dimension DZ3 of the step 39 in the thickness direction is greater than the distance DZ2 between the mount back surface 32R and the projection 37 in the Z-direction. This limits deformation of the mount portion 32.

(9) The method for manufacturing the semiconductor device 10 includes preparing the terminals 30, mounting the semiconductor chip 20 on the terminals 30, and forming the encapsulation resin 40 covering the terminals 30 and the semiconductor chip 20. The preparing the terminals 30 includes preparing the metal plate 820 including the head surface 30S and the back surface 30R facing away from each other, and selectively removing the metal plate 820 by etching from both the head surface 30S and the back surface 30R. The selectively removing the metal plate 820 forms the end surface 32A, which is an end surface of the terminal 30 in the first direction orthogonal to the thickness direction (the Z-direction), and the projection 37, which is located at the intermediate part of the end surface 32A in the Z-direction.

In this structure, the projection 37 is located at the intermediate part of the end surface 32A of the mount portion 32, rather than on the head-side edge 32AS or the back-side edge 32AR. This limits concentration of stress on one of the head-side edge 32AS and the back-side edge 32AR of the end surface 32A of the mount portion 32.

(10) The preparing the terminals 30 includes, by etching the back surface 30R of the terminals 30, forming the terminal portion 31 including the terminal back surface 31R, which is part of the back surface 30R exposed from the encapsulation resin 40, the mount portion 32 extending from the terminal portion 31 in the first direction, and the step 39 disposed between the mount portion 32 and the terminal portion 31 at a position closer to the head surface 30S than the terminal back surface 31R of the terminal portion 31 is.

In this structure, the step of forming the step 39 and the mount back surface 32R by etching from the back surface 30R of the terminal 30 is performed separately from the step of partially removing the lead frame 830 to separate each terminal 30 by etching from both the head surface 30S and the back surface 30R. In the comparative example, the method for manufacturing the semiconductor device 10X includes etching from both the head surface 30SX and the back surface 30RX of the terminal 30X. Therefore, the mount back surface 32RX is formed at the same time as the lead frame 830X is cut. With this method, the projection 37 is less likely to be formed at an edge (the back-side edge 32AR) of the end surface 32A than with the method for manufacturing the semiconductor device 10X of the comparative example.

### Modified Examples

The embodiments described above may be modified as follows. The modified examples described below may be combined as long as there is no technical contradiction.

The ratio of the thickness TB of the mount portion 32 to the thickness TC of the terminal portion 31 may be changed in any manner. In an example, the ratio of the thickness TB of the mount portion 32 to the thickness TC of the terminal portion 31 may be less than or equal to 1/2. The ratio of the thickness TB of the mount portion 32 to the thickness TC of the terminal portion 31 may be greater than 4/5. In an example, the ratio of the thickness TB of the mount portion 32 to the thickness TC of the terminal portion 31 may be in a range of greater than 4/5 and less than or equal to 5/6, less than or equal to 6/7, less than or equal to 7/8, less than or equal to 8/9, or less than or equal to 9/10.

The projection 37 may be located on the end surface 32A of the mount portion 32 at a position offset from the center in the Z-direction. The projection 37 may be located at any intermediate part of the end surface 32A between the head-side edge 32AS and the back-side edge 32AR in the Z-direction.

The projection 37 does not necessarily have to be formed on the entirety of the end surface 32A of the mount portion 32 in the width direction (second direction) of the mount portion 32. That is, the projection 37 may be formed on a portion of the end surface 32A in the second direction.

The step 39 connects the terminal back surface 31R and the mount back surface 32R in the Z-direction. Instead, for example, the step 39 may be separate from the terminal back surface 31R of the terminal portion 31 toward the head surface 30S of the terminal 30. In this case, for example, a side surface 30A extending in the Z-direction and the second direction may be formed between the step 39 and the terminal back surface 31R in the Z-direction.

In the method of manufacturing the semiconductor device 10, the step of forming the recess 821 by partially etching the head surface 820S of the metal plate 820 may be omitted.

The ratio of the length L2 of the mount portion 32 in the first direction to the length L1 of the terminal portion 31 in the first direction may be changed in any manner. The length L2 of the mount portion 32 in the first direction may be less than the length L1 of the terminal portion 31 in the first direction.

One or more of the various examples described in this specification may be combined as long as there is no technical contradiction.

In this specification, the word “on” includes the meaning of “above” in addition to the meaning of “on” unless otherwise described in the context. Accordingly, for example, the expression of “first element arranged on second element” may mean that the first element is arranged directly on the second element in one embodiment and mean that the first element is arranged above the second element without contacting the second element in another embodiment. In other words, the term “on” will also allow for a structure in which another element is formed between the first element and the second element.

The Z-direction as referred to in the present disclosure does not necessarily have to be the vertical direction and does not necessarily have to exactly coincide with the vertical direction. Accordingly, in the structures of the present disclosure, “up” and “down” with respect to the Z-direction as referred to in this specification are not limited to “up” and “down” with respect to the vertical direction. For example, the X-direction may be the vertical direction. Alternatively, the Y-direction may be the vertical direction.

### Clauses

The technical aspects that are understood from the present disclosure will hereafter be described. Reference characters used in the described embodiment are added to corresponding elements in the clauses to aid understanding without any intention to impose limitations on these elements. The reference characters are given as examples to aid understanding and are not intended to limit the elements in each clause to the elements denoted by the reference characters.

### Clause 1

A semiconductor device (10), including:

multiple terminals (30);

a semiconductor chip (20) mounted on the terminals (30); and

an encapsulation resin (40) encapsulating the terminals (30) and the semiconductor chip (20), where

each of the terminals (30) includes:

a back surface (30R) at least partially exposed from the encapsulation resin (40);

a head surface (30S) on which the semiconductor chip (20) is mounted;

an end surface (32A) disposed in the encapsulation resin (40), the end surface (32A) being an end in a first direction orthogonal to a thickness direction (Z-direction) of the terminals (30); and

a projection (37) located at an intermediate part of the end surface (32A) in the thickness direction (Z-direction).

### Clause 2

The semiconductor device according to clause 1, where the projection (37) is located at a central part of the end surface (32A) in the thickness direction (Z-direction).

### Clause 3

The semiconductor device according to clause 1 or 2, where

a direction that is orthogonal to the first direction and the thickness direction (Z-direction) is a second direction, and

the projection (37) extends on entirety of the end surface (32A) in the second direction.

### Clause 4

The semiconductor device according to any one of clauses 1 to 3, where

the projection (37) includes two side surfaces (37A, 37B) oriented oppositely with respect to the thickness direction (Z-direction),

each of the side surfaces (37A, 37B) includes a curved surface, the curved surfaces of the side surfaces (37A, 37B) being curved so as to approach each other toward a distal end of the projection (37).

### Clause 5

The semiconductor device according to any one of clauses 1 to 4, where

each of the terminals (30) includes:

a terminal portion (31) including a terminal back surface (31R), which is part of the back surface (30R) exposed from the encapsulation resin (40); and

a mount portion (32) extending in the encapsulation resin (40) from the terminal portion (31) in the first direction and including the end surface (32A), and

a ratio of a thickness (TB) of the mount portion (32) to a thickness (TC) of the terminal portion (31) is greater than 1/2.

### Clause 6

The semiconductor device according to clause 5, where the ratio of the thickness (TB) of the mount portion (32) to the thickness (TC) of the terminal portion (31) is less than or equal to 4/5.

### Clause 7

The semiconductor device according to clause 5 or 6, where

each of the terminals (30) includes a step (39) formed between the mount portion (32) and the terminal portion (31) so that a mount back surface (32R), which is part of the back surface (30R) corresponding to the mount portion (32), is located closer to the head surface (30S) than the terminal back surface (31R) of the terminal portion (31) is, and

a dimension (DZ3) of the step (39) in the thickness direction (Z-direction) is less than the thickness (TB) of the mount portion (32).

### Clause 8

The semiconductor device according to clause 7, where the step (39) includes a curved surface.

### Clause 9

The semiconductor device according to clause 7 or 8, where the dimension (DZ3) of the step (39) in the thickness direction is less than a distance (DZ2) between the mount back surface (32R) and the projection (37) in the thickness direction (Z-direction).

### Clause 10

The semiconductor device according to any one of clauses 1 to 9, where a length (L2) of the mount portion (32) in the first direction is greater than a length (L1) of the terminal portion (31) in the first direction.

### Clause 11

The semiconductor device according to any one of clauses 5 to 10, where each of the terminals (30) includes a back conductive film (34) covering the terminal back surface (31R).

### Clause 12

The semiconductor device according to any one of clauses 1 to 11, where each of the terminals (30) includes an exposed side surface (30AA) exposed from an encapsulation side surface (40A to 40D) of the encapsulation resin (40).

### Clause 13

The semiconductor device according to clause 12, where each of the terminals (30) includes a side conductive film (35) covering the exposed side surface (30AA).

### Clause 14

The semiconductor device according to any one of clauses 1 to 13, where the terminals (30) include Cu.

### Clause 15

The semiconductor device according to any one of clauses 1 to 14, where the terminals (30) are formed of a metal lead frame.

### Clause 16

A method for manufacturing a semiconductor device, the method including:

preparing multiple terminals (30);

mounting a semiconductor chip (20) on the terminals (30); and

forming an encapsulation resin (40) that encapsulates the terminals (30) and the semiconductor chip (20), where

the preparing multiple terminals (30) includes

preparing a metal plate (820) including a head surface (820S) and a back surface (820R) facing away from each other, and

selectively removing the metal plate (820) by etching from both the head surface (820S) and the back surface (820R), and

the selectively removing the metal plate (820) forms an end surface (32A) that is an end in a first direction orthogonal to a thickness direction (Z-direction) of the metal plate (820) and a projection (37) located at an intermediate part of the end surface (32A) in the thickness direction (Z-direction).

### Clause 17

The method according to clause 16, where the preparing multiple terminals (30) includes forming a recess (821) by partially etching the head surface (820S).

### Clause 18

The method according to clause 17, where the selectively removing the metal plate (820) includes further etching the recess (821) from the head surface (820S).

### Clause 19

The method according to any one of clauses 16 to 18, where the preparing multiple terminals (30) includes, by etching the back surface (820R), forming

a terminal portion (31) including a terminal back surface (31R) facing a same direction as the back surface (820R) in the thickness direction (Z-direction),

a mount portion (32) extending from the terminal portion (31) in the first direction, and

a step (39) formed between the mount portion (32) and the terminal portion (31) at a position closer to the head surface (820S) than the terminal back surface (31R) of the terminal portion (31) is.

### Clause 20

The method according to clause 19, further including:

cleaning the terminals (30) subsequent to forming the mount portion (32).

### Clause 21

A semiconductor device, including:

multiple terminals (30) each including a head surface (30S) and a back surface (30R) facing away from each other;

a semiconductor chip (20) mounted on the head surfaces (30S) of the terminals (30); and

an encapsulation resin (40) encapsulating the terminals (30) and the semiconductor chip (20), where

each of the terminals (30) includes:

a terminal portion (31) including a terminal back surface (31R) exposed from the encapsulation resin (40); and

a mount portion (32) extending from the terminal portion (31) in a first direction orthogonal to a thickness direction (Z-direction) of the terminals (30), the semiconductor chip (20) being mounted on the mount portion (32), and

a ratio of a thickness (TB) of the mount portion (32) to a thickness (TC) of the terminal portion (31) is greater than 1/2.

### Clause 22

The semiconductor device according to clause 21, where a ratio of a thickness (TB) of the mount portion (32) to a thickness (TC) of the terminal portion (31) is less than or equal to 4/5.

### Clause 23

The semiconductor device according to clause 21 or 22, where

the back surface (30R) includes a mount back surface (32R) corresponding to the mount portion (32), the mount back surface (32R) includes a step (39) formed between the mount portion (32) and the terminal portion (31) so that the step (39) is located closer to the head surface (30S) than the terminal back surface (31R) of the terminal portion (31),

a dimension (DZ3) of the step (39) in the thickness direction is less than the thickness (TB) of the mount portion (32).

### Clause 24

The semiconductor device according to any one of clauses 5 to 9 and 21 to 23, where the thickness (TB) of the mount portion (32) is greater than a thickness (TA) of the semiconductor chip (20).

### Clause 25

The semiconductor device according to clause 24, where a ratio of the thickness (TB) of the mount portion (32) to the thickness (TA) of the semiconductor chip (20) is greater than 1 and less than or equal to 1.8.

### Clause 26

A method for manufacturing a semiconductor device, the method including:

preparing multiple terminals (30);

mounting a semiconductor chip (20) on the terminals (30); and

forming an encapsulation resin (40) that encapsulates the terminals (30) and the semiconductor chip (20), where

the preparing multiple terminals (30) includes forming

a terminal portion (31) including a terminal back surface (31R) exposed from the encapsulation resin (40), and

a mount portion (32) extending from the terminal portion (31) in a first direction orthogonal to a thickness direction (Z-direction) of the terminals (30), the semiconductor chip (20) being mounted on the mount portion (32), and

the terminal portion (31) and the mount portion (32) are formed so that a ratio of a thickness (TB) of the mount portion (32) to a thickness (TC) of the terminal portion (31) is greater than 1/2.

### Clause 27

The method according to clause 26, where in the preparing multiple terminals (30), the terminal portion (31) and the mount portion (32) are formed so that the ratio of the thickness (TB) of the mount portion (32) to the thickness (TC) of the terminal portion (31) is less than or equal to 4/5.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
multiple terminals;
a semiconductor chip mounted on the terminals; and
an encapsulation resin encapsulating the terminals and the semiconductor chip, wherein
each of the terminals includes:
a back surface at least partially exposed from the encapsulation resin;
a head surface on which the semiconductor chip is mounted;
an end surface disposed in the encapsulation resin, the end surface being an end in a first direction orthogonal to a thickness direction of the terminals; and
a projection located at an intermediate part of the end surface in the thickness direction.

2. The semiconductor device according to claim 1, wherein the projection is located at a central part of the end surface in the thickness direction.

3. The semiconductor device according to claim 1, wherein
a direction that is orthogonal to the first direction and the thickness direction is a second direction, and
the projection extends on entirety of the end surface in the second direction.

4. The semiconductor device according to claim 1, wherein
the projection includes two side surfaces oriented oppositely with respect to the thickness direction,
each of the side surfaces includes a curved surface, the curved surfaces of the side surfaces being curved so as to approach each other toward a distal end of the projection.

5. The semiconductor device according to claim 1, wherein
each of the terminals includes:
a terminal portion including a terminal back surface, which is part of the back surface exposed from the encapsulation resin; and
a mount portion extending in the encapsulation resin from the terminal portion in the first direction and including the end surface, and
a ratio of a thickness of the mount portion to a thickness of the terminal portion is greater than 1/2.

6. The semiconductor device according to claim 5, wherein the ratio of the thickness of the mount portion to the thickness of the terminal portion is less than or equal to 4/5.

7. The semiconductor device according to claim 5, wherein
each of the terminals includes a step formed between the mount portion and the terminal portion so that a mount back surface, which is part of the back surface corresponding to the mount portion, is located closer to the head surface than the terminal back surface of the terminal portion is, and
a dimension of the step in the thickness direction is less than the thickness of the mount portion.

8. The semiconductor device according to claim 7, wherein the step includes a curved surface.

9. The semiconductor device according to claim 7, wherein the dimension of the step in the thickness direction is less than a distance between the mount back surface and the projection in the thickness direction.

10. The semiconductor device according to claim 5, wherein a length of the mount portion in the first direction is greater than a length of the terminal portion in the first direction.

11. The semiconductor device according to claim 5, wherein each of the terminals includes a back conductive film covering the terminal back surface.

12. The semiconductor device according to claim 1, wherein each of the terminals includes an exposed side surface exposed from an encapsulation side surface of the encapsulation resin.

13. The semiconductor device according to claim 12, wherein each of the terminals includes a side conductive film covering the exposed side surface.

14. The semiconductor device according to claim 1, wherein the terminals include Cu.

15. The semiconductor device according to claim 1, wherein the terminals are formed of a metal lead frame.

16. A method for manufacturing a semiconductor device, the method comprising:
preparing multiple terminals;
mounting a semiconductor chip on the terminals; and
forming an encapsulation resin that encapsulates the terminals and the semiconductor chip, wherein
the preparing multiple terminals includes
preparing a metal plate including a head surface and a back surface facing away from each other, and
selectively removing the metal plate by etching from both the head surface and the back surface, and
the selectively removing the metal plate forms an end surface that is an end in a first direction orthogonal to a thickness direction of the metal plate and a projection located at an intermediate part of the end surface in the thickness direction.

17. The method according to claim 16, wherein the preparing multiple terminals includes forming a recess by partially etching the head surface.

18. The method according to claim 17, wherein the selectively removing the metal plate includes further etching the recess from the head surface.

19. The method according to claim 16, wherein the preparing multiple terminals includes, by etching the back surface, forming
a terminal portion including a terminal back surface facing a same direction as the back surface in the thickness direction,
a mount portion extending from the terminal portion in the first direction, and
a step formed between the mount portion and the terminal portion at a position closer to the head surface than the terminal back surface of the terminal portion is.

20. The method according to claim 19, further comprising:
cleaning the terminals subsequent to forming the mount portion.
